(19) United States
(12) Patent Application Publication
(10) Pub. No.: US 2026/0120929 A1
(43) Pub. Date: Apr. 30, 2026

(54) SUPERCONDUCTING COIL DEVICE, SUPERCONDUCTING COIL, AND MAGNETIC RESONANCE IMAGING DEVICE

(71) Applicant: CANON MEDICAL SYSTEMS CORPORATION, Otawara-shi (JP)

(72) Inventors: Katsutoshi MIZUNO, Nasushiobara Tochigi (JP); Takehiro SHIBUYA, Nasushiobara Tochigi (JP)

(73) Assignee: CANON MEDICAL SYSTEMS CORPORATION, Otawara-shi (JP)

(21) Appl. No.: 19/369,452

(22) Filed: Oct. 27, 2025

(30) Foreign Application Priority Data
Oct. 30, 2024 (JP) 2024-190383

(51) Int. Cl. H01F 6/06; G01R 33/34; H01F 6/04

(52) U.S. Cl. CPC H01F 6/06; G01R 33/34023; H01F 6/04

(57) ABSTRACT

A superconducting coil device includes a plurality of superconducting coils which are stacked. Each of the plurality of superconducting coils includes a winding portion, a heat transfer plate, and a resin layer. The winding portion includes a high-temperature superconducting wire and a co-wound tape which are co-wound. The heat transfer plate is disposed on one side of the winding portion. The resin layer bonds the heat transfer plate to the winding portion. The width of the co-wound tape is less than a width of the high-temperature superconducting wire.

### CROSS-REFERENCE TO RELATED APPLICATION

The present application claims priority based on Japanese Patent Application No. 2024-190383 filed Oct. 30, 2024, the content of which is incorporated herein by reference.

### FIELD

Embodiments disclosed in this specification and drawings relate to a superconducting coil device, a superconducting coil, and a magnetic resonance imaging device.

### BACKGROUND

For example, magnetic resonance imaging devices use a superconducting coil device equipped with a high-temperature superconducting wire including a high-temperature superconducting magnet. As a high-temperature superconducting wire, REBCO (REBa2CuOy: RE is a rare earth element) wire has attracted attention, for example. Since REBCO wire is tape-shaped, superconducting coil devices are manufactured based on flat coils called pancake coils.

Since REBCO wire has low peel strength, when bonded using a resin as an adhesive, for example, it can easily peel depending on the thermal expansion coefficient and adhesive strength of the resin. Epoxy resin, in particular, has a high thermal expansion coefficient and adhesive strength, and thus using epoxy resin as an adhesive is likely to cause peeling and damage to the REBCO wire.

### BRIEF DESCRIPTION OF THE DRAWINGS

FIG. 1 is a diagram showing an overview of a superconducting coil device 1.

FIG. 2 is a plan view of a pancake coil 2 of a first embodiment.

FIG. 3 is a cross-sectional view taken along line III-III in FIG. 2.

FIG. 4 is an enlarged cross-sectional view of a main portion of a pancake coil 2A FIG. 5 is a cross-sectional view of a high-temperature superconducting wire 20.

FIG. 6 is a schematic diagram of a state in which the high-temperature superconducting wire 20 peels off.

FIG. 7 is a cross-sectional view of a pancake coil 2B of a second embodiment.

FIG. 8 is a cross-sectional view of a pancake coil 2C of a third embodiment.

FIG. 9 is a cross-sectional view of a main portion of a pancake coil 2D of a fourth embodiment.

FIG. 10 is a cross-sectional view of one turn in a lower winding portion 12D of the pancake coil of the fourth embodiment.

FIG. 11 is a diagram showing a modified example of a winding portion 12.

### DETAILED DESCRIPTION

Hereinafter, a superconducting coil device, a superconducting coil, a magnetic resonance imaging device, and a method of manufacturing a superconducting coil device of an embodiment will be described with reference to the drawings. The superconducting coil device of the embodiment is used, for example, in a magnetic resonance imaging device (hereinafter referred to as an MRI device). The superconducting coil device is formed by stacking a plurality of pancake coils.

The superconducting coil device includes a plurality of superconducting coils which are stacked. Each of the plurality of superconducting coils includes a winding portion, a heat transfer plate, and a resin layer. The winding portion includes a high-temperature superconducting wire and a co-wound tape which are co-wound. The heat transfer plate is disposed on one side of the winding portion. The resin layer bonds the heat transfer plate to the winding portion. The width of the co-wound tape is less than a width of the high-temperature superconducting wire.

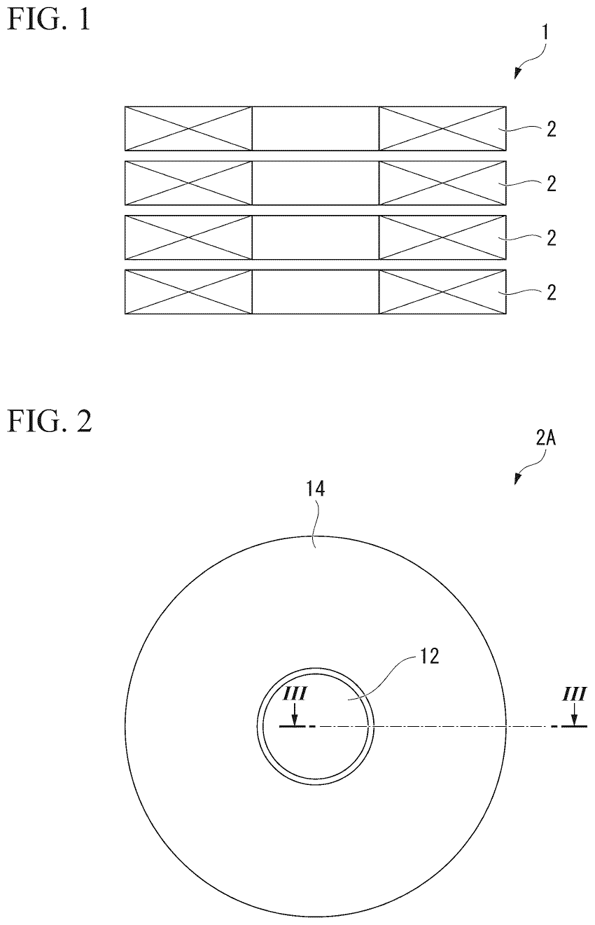

FIG. 1 is a diagram showing an overview of a superconducting coil device 1. The superconducting coil device 1 is formed, for example, by stacking a plurality of superconducting coils, for example, a plurality of pancake coils 2. The superconducting coil device 1 is formed as a large coil by stacking and connecting the plurality of pancake coils 2. The superconducting coil device 1 can be used as a magnet, and is installed, for example, in an MRI device (not shown) to generate magnetic fields around a subject.

The plurality of pancake coils 2 have the same configuration. The pancake coils 2 may be configured in various ways. Various structures of the pancake coils 2 will be described below using different embodiments. In the following description, a different alphabetical character will be added to the reference numeral “2” for the pancake coils 2 depending on the embodiment. The superconducting coil device 1 may be configured by stacking pancake coils 2 of the same structure, or by stacking pancake coils 2 of different structures.

### First Embodiment

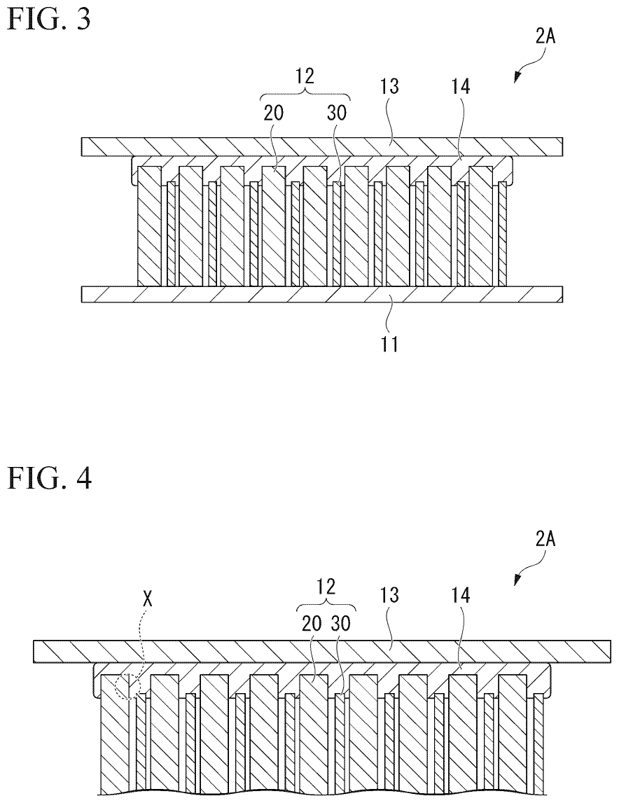

FIG. 2 is a plan view of a pancake coil 2A of a first embodiment, and FIG. 3 is a cross-sectional view taken along line III-III in FIG. 2. The pancake coil 2A includes, for example, a bottom plate 11, a high-temperature superconducting wire winding portion (hereinafter referred to as a winding portion) 12, a heat transfer plate 13, and a resin layer 14. The winding portion 12 includes, for example, a high-temperature superconducting wire 20 and a co-wound tape 30. FIG. 2 does not depict the heat transfer plate 13. The pancake coil 2A is a single pancake coil in which a single layer of the winding portion 12 is formed.

The bottom plate 11 is, for example, a thin plate having an opening at a position corresponding to an inner frame W1. The winding portion 12 is provided on one side of the bottom plate 11, the upper side in the first embodiment. The winding portion 12 is formed by being wound around the inner frame W1 provided in the approximate center of one side of the bottom plate 11. The winding portion 12 is provided on the bottom plate 11 with the lower ends of the high-temperature superconducting wire 20 and the co-wound tape 30 abutting the bottom plate 11. As shown in FIG. 3, the width of the co-wound tape 30 is less than the width of the high-temperature superconducting wire 20, and the co-wound tape is positioned closer to the opposite side (lower side) of the winding portion 12 than to the one side (upper side) of the winding portion 12.

The inner frame W1 is made of, for example, glass-fiber-reinforced plastics, oxygen-free copper, stainless steel, aluminum alloy, or the like. The winding portion 12 is formed by co-winding the high-temperature superconducting wire 20 and the co-wound tape 30 around the inner frame W1.

The heat transfer plate 13 is bonded to the winding portion 12 by the resin layer 14. The heat transfer plate 13 is, for example, disk-shaped. The heat transfer plate 13 may have an opening at a position corresponding to the central inner frame W1, or May have the shape of two opposing half-rings formed by dividing a disk with an opening in the center in half.

The heat transfer plate 13 is formed of, for example, a metal with high thermal conductivity. The heat transfer plate 13 may also be made of a material other than metal, such as resin. Since the width of the co-wound tape 30 is less than the width of the high-temperature superconducting wire 20, the co-wound tape 30 is positioned at a distance from the heat transfer plate 13. Since the thermal conductivity of the heat transfer plate 13 is higher than that of the resin layer 14, the cooling efficiency of the winding portion 12, particularly, the high-temperature superconducting wire 20, can be improved by disposing the heat transfer plate 13.

The resin layer 14 is formed between the winding portion 12 and the heat transfer plate 13. The resin layer 14 is formed, for example, by being coated on one side of the winding portion 12. The resin layer 14 is composed of, for example, an ethylene-methacrylic acid copolymer, a silylated urethane resin, a modified silicon resin, or an epoxy resin.

In the first embodiment, the resin layer 14 is composed of a highly viscous resin, such as an ethylene-methacrylic acid copolymer, a silylated urethane resin, a modified silicone resin, or an epoxy resin with a viscosity of 4000 cP or higher. Since the heat transfer plate 13 and the co-wound tape 30 are separated, the resin layer 14 is formed by penetrating between the heat transfer plate 13 and the co-wound tape 30.

The resin layer 14 abuts the sides of both sides of the upper end of the high-temperature superconducting wire 20. The resin layer 14 has high viscosity and thus is formed, for example, by applying the resin to one surface (top surface) of the winding portion 12, which is formed by co-winding the high-temperature superconducting wire 20 and the co-wound tape 30 on the inner frame W1, and then curing the resin. By placing the heat transfer plate 13 before the resin is cured, the heat transfer plate 13 is bonded to the winding portion 12 by the resin layer 14 formed by the cured resin.

FIG. 4 is an enlarged cross-sectional view of a main portion of the pancake coil 2A. The winding portion 12 of the pancake coil 2A is formed by co-winding the high-temperature superconducting wire 20 and the co-wound tape, with the co-wound tape 30 interposed between turns of the high-temperature superconducting wire 20. The width of the co-wound tape 30 is less than that of the high-temperature superconducting wire 20, and the heat transfer plate 13 and the co-wound tape 30 are separated.

In the area where the heat transfer plate 13 and the co-wound tape 30 are separated, the resin layer 14 is formed to bond the heat transfer plate 13 to the winding portion 12. The resin layer 14 is bonded to the end of the heat transfer plates 13 on both sides of the high-temperature superconducting wire 20 and the end surface of the high-temperature superconducting wire 20 on the side of the heat transfer plate 13. The winding portion 12 includes a bonded portion (portion “X” shown in FIG. 4) that is bonded to the resin layer 14, and a non-bonded portion to which the resin layer 14 is not bonded. In the first embodiment, the non-bonded portion is the area below the area where the resin layer 14 is formed.

The high-temperature superconducting wire 20 is, for example, a REBCO wire. FIG. 5 is a cross-sectional view of the high-temperature superconducting wire 20. The high-temperature superconducting wire 20 includes a substrate 21, intermediate layers 22, a superconducting layer 23, an inner protective layer 24, and an outer protective layer 25. The substrate 21, the intermediate layers 22, and the superconducting layer 23 are stacked in this order. The inner protective layer 24 completely covers and protects the outer surface of the stacked substrate 21, intermediate layers 22, and superconducting layer 23, and the outer protective layer 25 completely covers and protects the outer surface of the inner protective layer 24.

The width of the high-temperature superconducting wire 20 is, for example, between 2 mm and 12 mm, and is, for example, 4 mm in this example. The substrate 21 is, for example, a metal substrate made of metal. Examples of metals used for the substrate 21 include nickel alloys and stainless steel. The thickness of the substrate 21 is, for example, 50 μm.

The intermediate layers 22 are composed of, for example, one or more of gadolinium-zirconium oxide (Gd—Zr oxide), magnesium oxide (MgO), yttrium-stabilized zirconium (YSZ), barium-zirconium oxide (Ba—Zr oxide), and cerium oxide (CeO2). The thickness of the intermediate layers 22 is, for example, approximately 0.5 μm.

The superconducting layer 23 is formed by depositing a rare-earth oxide superconductor onto the intermediate layers 22 using a chemical vapor deposition (CVD) method, for example. The thickness of the superconducting layer 23 is, for example, approximately 1 μm. Examples of rare earth elements include lanthanum (La), neodymium (Nd), samarium (Sm), europium (Eu), gadolinium (Gd), dysprosium (Dy), holmium (Ho), erbium (Er), yttrium (Y), ytterbium (Yb), and the like. Examples of rare earth oxides include RE-Ba—Cu—O. Here, RE represents a rare earth element. Specific examples of the superconducting layer 23 include yttrium-barium-copper oxide and lanthanum-barium-copper oxide (La—Ba—Cu oxide).

The inner protective layer 24 is made of, for example, silver. The thickness of the inner protective layer 24 is, for example, 2 μm. The inner protective layer 24 is made of, for example, copper. The thickness of the outer protective layer 25 is, for example, 20 μm. The substrate 21, intermediate layers 22, and superconducting layer 23 have the same width, the width of the inner protective layer 24 is greater than that of the substrate 21, intermediate layers 22, and superconducting layer 23, and the width of the outer protective layer 25 is further greater than that of the substrate 21, intermediate layers 22, and superconducting layer 23.

The ratio of the differences between the width of the substrate 21, intermediate layers 22, and superconducting layer 23, the inner protective layer 24, and the outer protective layer 25 and the width of the high-temperature superconducting wire 20 is very low. Therefore, the differences between the width of the substrate 21, intermediate layers 22, and superconducting layer 23, the inner protective layer 24, and the outer protective layer 25 are minimal.

The co-wound tape 30 is tape-shaped. The co-wound tape 30 is an insulating tape made of an insulating material such as polyimide. The co-wound tape 30 may also be a stainless steel tape and the like. The width of the co-wound tape 30 is less than that of the high-temperature superconducting wire 20 and is also less than the width of the superconducting layer 23 of the high-temperature superconducting wire 20.

The co-wound tape 30 is disposed closer to the opposite side (lower side) of the winding portion 12 than to one side (upper side). The co-wound tape 30 is wound around the inner frame W1 while overlapping the high-temperature superconducting wire 20. The co-wound tape 30 is interposed between turns of the high-temperature superconducting wire 20, thereby preventing short-circuits between the turns of the high-temperature superconducting wire 20.

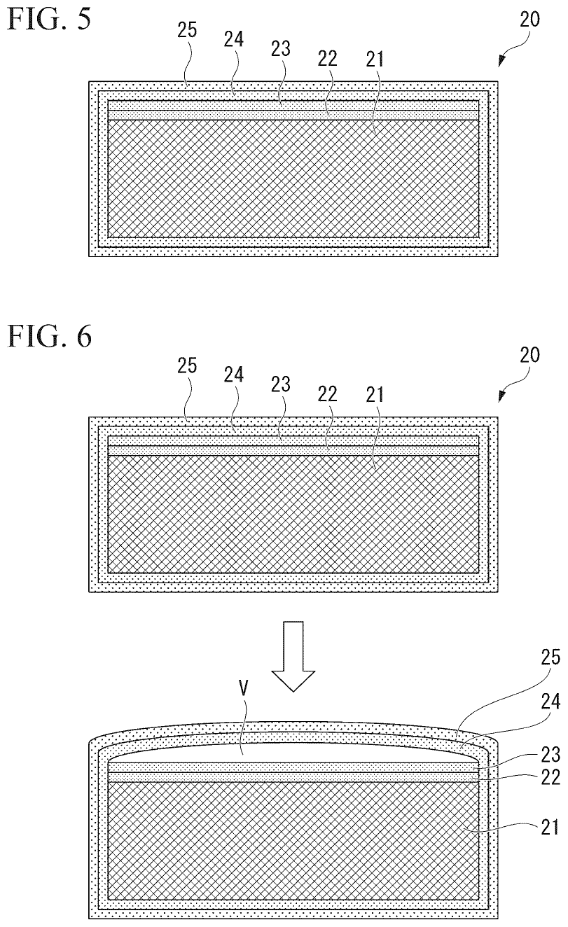

In the superconducting coil device 1, damage occurs to the high-temperature superconducting wire 20 due to thermal stress associated with cooling. The mechanism of damage to the high-temperature superconducting wire 20 will now be described. FIG. 6 is a schematic diagram showing a state in which the high-temperature superconducting wire 20 peels off. Damage to the high-temperature superconducting wire 20 in the pancake coil 2A is often caused by delamination in the high-temperature superconducting wire 20.

In the high-temperature superconducting wire 20 shown in the upper part of FIG. 6, delamination occurs mainly between the superconducting layer 23 and the inner protective layer 24, as shown in the lower part of FIG. 6, and the delamination space Vis formed between the superconducting layer 23 and the inner protective layer 24, for example. Furthermore, delamination between the superconducting layer 23 and the inner protective layer 24 mainly occurs in the center of the high-temperature superconducting wire 20 in the width direction.

If the width of the co-wound tape 30 is equal to or greater than the width of the high-temperature superconducting wire 20 and the heat transfer plate 13 and the co-wound tape 30 are not separated, only the end surface of the high-temperature superconducting wire 20 comes into contact with the resin layer 14. In this case, the contact area of the high-temperature superconducting wire 20 with respect to the heat transfer plate 13 is small, making it difficult to ensure sufficient heat transfer.

On the other hand, in the pancake coil 2A of the first embodiment, the resin layer 14 is formed on the side of the heat transfer plate 13 of the co-wound tape 30 between the turns of the high-temperature superconducting wire 20. Therefore, the end surfaces and both end surfaces of the high-temperature superconducting wire 20 abut against the resin layer 14 between the turns. Accordingly, compared to the case in which only the end surface of the high-temperature superconducting wire 20 comes into contact with the resin layer 14, the contact area between the high-temperature superconducting wire 20 and the resin layer 14 is wider, thereby improving heat transfer.

In the pancake coil 2A of the first embodiment, the width of the co-wound tape 30 is less than that of the high-temperature superconducting wire 20, and thus the heat transfer plate 13 is bonded to the end of the high-temperature superconducting wire 20 in the width direction, one end on one side in the first embodiment, by the resin layer 14. This ensures a heat transfer path between the heat transfer plate 13 and the superconducting layer 23 of the high-temperature superconducting wire 20 via the resin layer 14, the outer protective layer 25, and the inner protective layer 24, thereby preventing decrease in the cooling efficiency of the superconducting layer 23.

Furthermore, in the pancake coil 2A of the first embodiment, the non-bonded portion that is not bonded to the resin layer 14 is formed in the area of the winding portion 12 below the portion bonded to the resin layer 14. Therefore, the heat transfer path from the heat transfer plate 13 to the superconducting layer 23 of the high-temperature superconducting wire 20 is limited to one end side of the high-temperature superconducting wire 20. Therefore, peeling between the superconducting layer 23 and the inner protective layer 24 can be suppressed.

### Second Embodiment

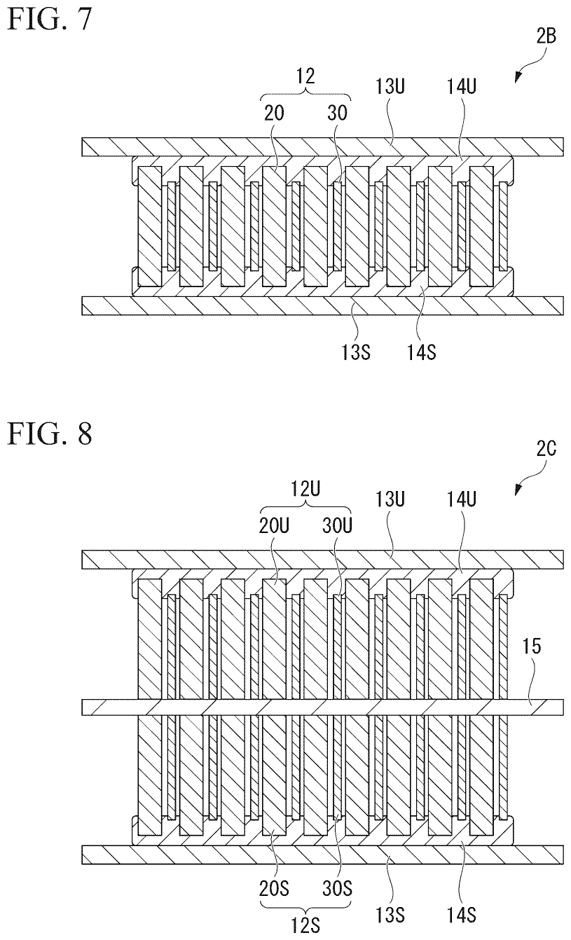

Next, a pancake coil 2B according to a second embodiment will be described. FIG. 7 is a cross-sectional view of the pancake coil 2B of the second embodiment. The pancake coil 2B of the second embodiment differs from the pancake coil 2A of the first embodiment mainly in that the heat transfer plate 13 is bonded to both of one side and the other side of the winding portion 12. Hereinafter, the pancake coil 2B of the second embodiment will be described, focusing on the differences from the first embodiment. In the following description, components common to the embodiments will be denoted by the same reference numerals, and detailed description may be omitted.

The pancake coil 2B of the second embodiment includes a winding portion 12 similar to that of the first embodiment, and the winding portion 12 is formed by co-winding the high-temperature superconducting wire 20 and the co-wound tape 30. An upper heat transfer plate 13U is bonded to the upper part of the winding portion 12 by an upper resin layer 14U. A lower heat transfer plate 13S is bonded to the lower part of the winding portion 12 by a lower resin layer 14S.

The width of the co-wound tape 30 is less than the width of the high-temperature superconducting wire 20, and there is a gap between the upper heat transfer plate 13U and the co-wound tape 30 and between the lower heat transfer plate 13S and the co-wound tape 30. The upper resin layer 14U is formed between the co-wound tape 30 and the upper heat transfer plate 13U, and the lower resin layer 14S is formed between the co-wound tape 30 and the lower heat transfer plate 13S.

The superconducting coil device 1 equipped with the pancake coil 2B of the second embodiment achieves the same effects as the superconducting coil device 1 equipped with the pancake coil 2A of the first embodiment. In the superconducting coil device 1 equipped with the pancake coil 2B of the second embodiment, the winding portion 12 is cooled by the upper heat transfer plate 13U and the lower heat transfer plate 13S. This further improves the cooling efficiency of the winding portion 12.

### Third Embodiment

Next, a pancake coil 2C of a third embodiment will be described. FIG. 8 is a cross-sectional view of the pancake coil 2C of the third embodiment. The pancake coil 2C of the third embodiment differs from the first embodiment mainly in that the pancake coil 2C includes a double pancake coil with two layers of winding portions whereas the pancake coil 2A of the first embodiment includes a single pancake coil with a single layer of winding portion.

The pancake coil 2C of the third embodiment includes, for example, an upper winding portion 12U, an upper heat transfer plate 13U, an upper resin layer 14U, a lower winding portion 12S, a lower heat transfer plate 13S, and a lower resin layer 14S. The upper winding portion 12U includes an upper high-temperature superconducting wire 20U and an upper co-wound tape 30U.

The lower winding portion 12S includes, for example, a lower high-temperature superconducting wire 20S and a lower co-wound tape 30S. A separator 15 is provided between the upper winding portion 12U and the lower winding portion 12S. The upper winding portion 12U, the upper heat transfer plate 13U, and the upper resin layer 14U are connected upside down to the lower winding portion 12S, lower heat transfer plate 13S, and lower resin layer 14S, with the separator 15 sandwiched therebetween.

The upper heat transfer plate 13U is disposed on the opposite side (lower side) of the upper winding portion 12U from the side facing the lower winding portion 12S, and the lower heat transfer plate 13S is disposed on the opposite side (upper side) of the lower winding portion 12S from the side facing the upper winding portion 12U. The upper co-wound tape 30U is disposed closer to the lower surface side than the upper surface side of the upper winding portion 12U, and the lower co-wound tape 30S is disposed closer to the upper surface side than the lower surface side of the lower winding portion 12S. The superconducting coil device 1 including the double-pancake pancake coil 2C in the third embodiment can also improve the uniformity of the winding thickness of the high-temperature superconducting wire.

### Fourth Embodiment

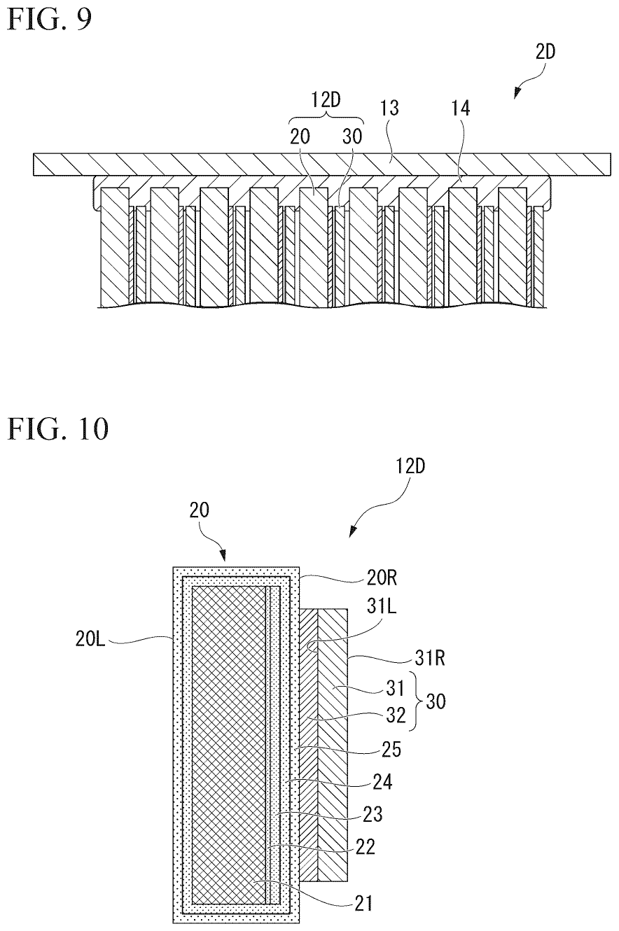

Next, a pancake coil 2D of a fourth embodiment will be described. FIG. 9 is a cross-sectional view of a main portion of the pancake coil 2D of the fourth embodiment. The pancake coil 2D of the fourth embodiment differs from the pancake coil 2A of the first embodiment mainly with respect to the configuration of the winding portion and the resin forming the resin layer.

In the pancake coil 2D of the fourth embodiment, the resin layer 14 is made of, for example, an epoxy resin with a viscosity of less than 4000 cP. An epoxy resin with a viscosity of less than 4000 cP has low viscosity. A winding portion 12D of the pancake coil 2D of the fourth embodiment includes, for example, a high-temperature superconducting wire 20 and a co-wound tape 30.

FIG. 10 is a cross-sectional view of one turn in the winding portion 12D of the pancake coil of the fourth embodiment. The high-temperature superconducting wire 20 is formed, for example, in the same shape and made of the same material as in the first embodiment. The co-wound tape 30 includes, for example, a co-wound tape substrate 31 and an adhesive layer 32. The co-wound tape substrate 31 of the co-wound tape 30 is made of, for example, polyimide, as in the co-wound tape 30 of the first embodiment, but may also be made of stainless steel and the like.

The adhesive layer 32 is formed between the high-temperature superconducting wire 20 and the co-wound tape substrate 31 and adheres one surface 31L of the co-wound tape substrate 31 (the left surface in FIG. 9, hereinafter referred to as a substrate left surface) to the surface 20R of the high-temperature superconducting wire 20 closer to the position where the superconducting layer 23 is formed (the right surface in FIG. 9, hereinafter referred to as a wire right surface). The adhesive layer 32 adheres the co-wound tape 30 to the high-temperature superconducting wire 20, for example.

The co-wound tape substrate 31 is adhered to the wire right surface 20R by the adhesive layer 32, and the surface 20L of the high-temperature superconducting wire 20 closer to the position where the substrate 21 is formed (the left surface in FIG. 9, hereinafter referred to as a wire left surface) is open. As described with reference to FIG. 6, peeling in the high-temperature superconducting wire 20 often occurs between the superconducting layer 23 and the inner protective layer 24, which are closer to the wire right surface 20R than to the wire left surface 20L. Therefore, by adhering the co-wound tape substrate 31 to the wire right surface 20R through the adhesive layer 32, peeling in the high-temperature superconducting wire 20 can be suppressed.

The superconducting coil device 1 including the pancake coil 2D of the fourth embodiment achieves the same effects as the superconducting coil device 1 including the pancake coil 2A of the first embodiment. Furthermore, in the superconducting coil device 1 including the pancake coil 2D of the fourth embodiment, in the winding portion 12D, the co-wound tape substrate 31 is adhered to the high-temperature superconducting wire 20 by the adhesive layer 32. Therefore, it is possible to suppress displacement of the co-wound tape 30 relative to the high-temperature superconducting wire 20, and therefore it is possible to suppress short-circuits between turns of the high-temperature superconducting wire 20.

The resin layer 14 in the fourth embodiment uses an epoxy resin having a low viscosity of less than 4000 cP. Therefore, during the manufacturing process of the resin layer 14, for example, the resin that will become the resin layer 14 after solidification (hereinafter referred to as a pre-solidified resin) may flow between the high-temperature superconducting wire 20 and the co-wound tape 30 in the winding portion 12, raising concerns that the resin layer may spread between the high-temperature superconducting wire 20 and the co-wound tape 30. Since epoxy resin has strong adhesive strength, bonding the high-temperature superconducting wire 20 and the co-wound tape 30 using epoxy resin can cause damage to the high-temperature superconducting wire 20.

In this regard, the adhesive layer 32 is formed between the wire right surface 20R and the substrate left surface 31L. Therefore, the adhesive layer 32 prevents the pre-solidified resin from flowing into the wire right surface 20R and the substrate left surface 31L, preventing a high adhesive force from being exerted between the high-temperature superconducting wire 20 and the co-wound tape substrate 31. Accordingly, it is possible to suppress damage to the high-temperature superconducting wire 20 due to peeling between the substrate 21 and the superconducting layer 23.

Further, although there is also the concern that the pre-solidified resin may flow between the substrate right surface 31R and the wire left surface 20L of the adjacent turn to the right, the substrate 21 is provided on the side of the wire left surface 20L of the high-temperature superconducting wire 20. Therefore, even if the substrate right surface 31R and the wire left surface 20L are bonded with epoxy resin, the adhesive force is absorbed by the thick substrate 21, reducing the force that would peel the substrate 21 from the superconducting layer 23, and thus it is possible to suppress damage to the high-temperature superconducting wire 20 due to peeling between the substrate 21 and the superconducting layer 23.

In the pancake coil 2D of the fourth embodiment, the surface 31R opposite the substrate left surface 31L (the surface on the right in FIG. 9, hereinafter referred to as a substrate left surface) is not in contact with the high-temperature superconducting wire 20 of the adjacent turn to the right, but the substrate right surface 31R may be in contact with the wire left surface 20L of the adjacent turn to the right. Although the adhesive layer 32 is formed on one surface (substrate left surface 31L) of the co-wound tape substrate 31, it may also be formed on both surfaces (substrate left surface 31L and substrate right surface 31R) of the co-wound tape substrate 31. In this case, the co-wound tape substrate 31 may be adhered to the wire right surface 20R and the wire left surface 20L between the turns of the high-temperature superconducting wire 20.

### (Modified Examples of Winding Portion 12)

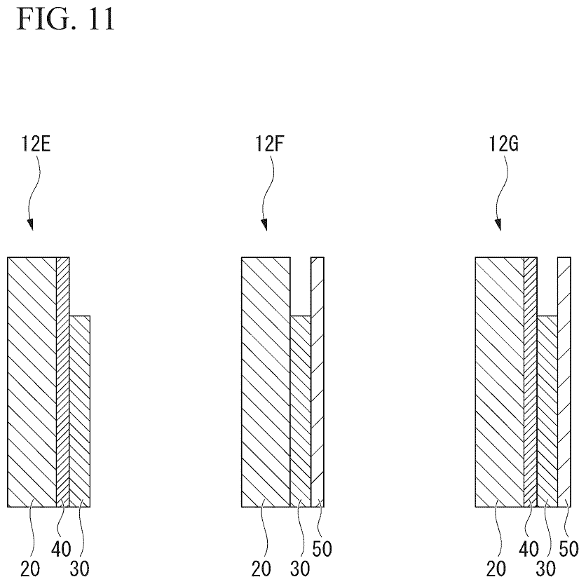

Modified examples of the winding portion 12 will be described below. FIG. 11 shows modified examples of the winding portion 12. The left side of FIG. 11 shows a cross-sectional view of a winding portion 12E of a first modified example. The center of FIG. 11 shows a cross-sectional view of a winding portion 12F of a second modified example. The right side of FIG. 11 shows a cross-sectional view of a winding portion 12G of a third modified example.

The winding portion 12E of the first modified example is configured by stacking a high-temperature superconducting wire 20, an insulating tape 40, and a co-wound tape 30 in this order, with the insulating tape 40 interposed between the high-temperature superconducting wire 20 and the co-wound tape 30. In the winding portion 12E of the first modified example, the high-temperature superconducting wire 20 has the same configuration as in the above embodiments. The co-wound tape 30 is formed of, for example, an insulating material such as polyimide or a conductive material such as stainless steel, and the width thereof is less than the width of the high-temperature superconducting wire 20.

The insulating tape 40 is formed of, for example, polyimide, and the width thereof is equal to or greater than the high-temperature superconducting wire 20. The winding portion 12E of the first modified example is provided with the insulating tape 40 having the width that is equal to or greater than that of the high-temperature superconducting wire 20, thereby ensuring insulation to the ends of the high-temperature superconducting wire 20.

The winding portion 12F of the second modified example is formed by stacking a high-temperature superconducting wire 20, a co-wound tape 30, and a spacer 50 in this order. In the winding portion 12F of the second modified example, the high-temperature superconducting wire 20 has the same configuration as in the above embodiments. The co-wound tape 30 is formed of an insulating material such as polyimide, and the width thereof is less than that of the high-temperature superconducting wire 20.

The spacer 50 is formed of a conductive material such as stainless steel, and the width thereof is equal to or greater than the width of the high-temperature superconducting wire 20. The spacer 50 adjusts the inter-turn width of the winding portion 12F of the second modified example, for example, and serves to adjust the magnetic field when designing the superconducting coil device 1. When the spacer 50 is provided, the co-wound tape 30 is used as an insulating material.

The winding portion 12G of the third modified example is configured by stacking a high-temperature superconducting wire 20, an insulating tape 40, a co-wound tape 30, and a spacer 50 in this order. In the winding portion 12G of the third modified example, the high-temperature superconducting wire 20 has the same configuration as in the above embodiments. The co-wound tape 30 is formed of an insulating material such as polyimide or a conductive material such as stainless steel, and the width thereof is less than the width of the high-temperature superconducting wire 20.

The insulating tape 40 is formed of, for example, polyimide, and the width thereof is equal to or greater than the width of the high-temperature superconducting wire 20. The spacer 50 is formed of, for example, a conductive material such as stainless steel, and the width thereof is equal to or greater than the width of the high-temperature superconducting wire 20. The spacer 50 adjusts the inter-turn width of the winding portion 12G of the third modified example, and serves to adjust the magnetic field when designing the superconducting coil device 1. The winding portion 12G of the third modified example is provided with the insulating tape 40 having the width that is equal to or greater than the width of the high-temperature superconducting wire 20, thereby ensuring insulation to the ends of the high-temperature superconducting wire 20.

According to at least one embodiment described above, in the superconducting coil device in which a plurality of superconducting coils are stacked, the superconducting coil includes a winding portion in which a high-temperature superconducting wire and a co-wound tape are co-wound, a heat transfer plate disposed on one side of the winding portion, and a resin layer that bonds the heat transfer plate to the winding portion, and the width of the co-wound tape is less than the width of the high-temperature superconducting wire, thereby suppressing damage to the high-temperature superconducting wire.

Although several embodiments have been described, these embodiments are presented as examples and are not intended to limit the scope of the invention. These embodiments can be implemented in various other forms, and various omissions, substitutions, and modifications can be made without departing from the spirit of the invention. These embodiments and modifications thereof are included in the scope and spirit of the invention, as well as the scope of the invention described in the claims and equivalents thereof.

What is claimed is:

1. A superconducting coil device comprising a plurality of superconducting coils which are stacked, wherein each of the plurality of superconducting coils comprises:
a winding portion comprising a high-temperature superconducting wire and a co-wound tape which are co-wound;
a heat transfer plate disposed on one side of the winding portion; and
a resin layer that bonds the heat transfer plate to the winding portion,
wherein a width of the co-wound tape is less than a width of the high-temperature superconducting wire.

2. The superconducting coil device according to claim 1, wherein at least a portion of spaces between turns in the winding portion comprises a non-bonded portion on which bonding by the resin layer is not performed.

3. The superconducting coil device according to claim 1, wherein the high-temperature superconducting wire comprises a superconducting layer,
wherein the width of the co-wound tape is less than a width of the superconducting layer.

4. The superconducting coil device according to claim 1, wherein
the co-wound tape comprises a co-wound tape substrate and an adhesive layer that adheres the co-wound tape substrate to the high-temperature superconducting wire, and
a resin that constitutes the resin layer comprises an epoxy resin having a viscosity of less than 4000 cP.

5. The superconducting coil device according to claim 1, wherein
the co-wound tape comprises a co-wound tape substrate and does not comprise an adhesive layer that adheres the co-wound tape substrate to the high-temperature superconducting wire, and
a resin that constitutes the resin layer comprises an ethylene-methacrylic acid copolymer, a silylated urethane resin, a modified silicon resin, or an epoxy resin having a viscosity of 4000 cP or more.

6. The superconducting coil device according to claim 1, wherein
each of the plurality of superconducting coils comprises a single pancake coil in which the winding portion is formed in one layer,
the heat transfer plate is disposed on both sides of the winding portion, and
the co-wound tape is disposed spaced apart from the heat transfer plate.

7. The superconducting coil device according to claim 1, wherein
each of the plurality of superconducting coils comprises a single pancake coil in which the winding portion is formed in one layer,
the heat transfer plate is disposed on one side of the winding portion, a bottom plate is disposed on the opposite side opposite the one side, and
the co-wound tape is disposed closer to the opposite side than the one side.

8. The superconducting coil device according to claim 1, wherein
each of the plurality of superconducting coils comprises a double pancake coil in which the winding portion is formed in two layers,
the heat transfer plate is disposed on one side of each of the two layers of winding portion opposite a facing side of each of the two layers of winding portion, and
the co-wound tape is disposed closer to the facing side than the one side.

9. The superconducting coil device according to claim 1, wherein the co-wound tape is made of an insulating material.

10. The superconducting coil device according to claim 1, wherein an insulating tape having a width equal to or greater than the width of the high-temperature superconducting wire is interposed between the co-wound tape and the high-temperature superconducting wire.

11. The superconducting coil device according to claim 9, wherein the co-wound tape comprises a co-wound tape substrate and a spacer that adjusts an inter-turn width of the winding portion.

12. A superconducting coil in a superconducting coil device comprises a plurality of superconducting coils which are stacked, the superconducting coil comprising:
a winding portion comprising a high-temperature superconducting wire and a co-wound tape which are co-wound;
a heat transfer plate disposed on one side of the winding portion; and
a resin layer that bonds the heat transfer plate to the winding portion,
wherein a width of the co-wound tape is less than a width of the high-temperature superconducting wire.

13. A magnetic resonance imaging device comprising the superconducting coil device according to claim 1.
